(19) United States
(12) Patent Application Publication
(10) Pub. No.: US 2008/0191218 A1
(43) Pub. Date: Aug. 14, 2008

(54) Low-Dielectric Constant Cryptocrystal Layers And Nanostructures

(76) Inventor: Seref Kalem, Kocaeli (TR)

Correspondence Address: VENABLE, CAMPILLO, LOGAN & MEANEY, P.C., 1938 E. OSBORN RD, PHOENIX, AZ, 85016-7234, US

(21) Appl. No.: 11/908,778

(22) PCT Filed: Feb. 8, 2006
(86) PCT No.: PCT/IB06/50406

§ 371 Date: Sep. 14, 2007

(30) Foreign Application Priority Data
Mar. 16, 2005 (TR) 2005/00923

(51) Int. Cl. H01L 21/469; H01L 23/52; H01L 29/737; H01L 33/00; H01L 21/46

(52) U.S. Cl. 257/79; 438/778; 257/734; 257/197; 438/455; 257/E21.487; 257/E23.141; 257/E29.188; 257/E33.001; 257/E21.482

(57) ABSTRACT

This invention provides a method for producing application quality low-dielectric constant (low-k) cryptocrystal layers on state-of-the-art semiconductor wafers and for producing organized Nanostructures from cryptocrystals and relates to optical and electronic devices that can be obtained from these materials. The results disclosed here indicate that modification of structure and chemical composition of single crystal matrix using chemical vapor processing (CVP) results in high quality cryptocrystal layers that are homogeneous and form a smooth interface with semiconductor wafer With this method, growth rates as high as 1 μm/hour can be realized for the dielectric cryptocrystal layer formation. The present invention also provides a method for producing Micro- and Nano-wires by transforming cryptocrystals to organized systems. With this method, Nano wires having dimensions ranging from few nanometers up to 1000 nanometer and lengths up to 50 micrometer can be produced. The cryptocrystals, nanowires and organized structures may be used in future interconnections as interlevel and intermetal di-electrics, in producing ultra high density memory cells, in information security as key generators, in producing photonic componenst, in fabrication of cooling channnels in advanced micro- and nano-electronics packaging and sensors.

The present invention relates to low-dielectric constant cryptocrystals that may be used in conjunction with future generation integrated circuits and devices. The cryptocrystal stands for a material that is so finely grained that no distinct particles are discerned under optical microscope and even under electron microscope. State of matter arranged in this way with such minute crystals is said to be cryptocrystal This type of crystals can exhibit extraordinary dielectric properties which can be used in various fields.

The invention relates to cryptocrystals and particularly to Ammonium Silicon Fluoride (ASIF), which have been derived from state-of-the-art wafers and having a general formula (NH₄)₂XF₆—(wherein X=Si, Ge, C) named as ‘ammonium X-fluoride’.

There is no report in literature on the above mentioned optical quality dielectric Ammonium X-Fluoride cryptocrystals.

Ammonium Silicon Fluoride (ASiF) material was shown to be formed on Silicon wafers when Ammonium Fluoride NH₄F is reacted with Si on the wafer surface [M. Niwano, K. Kurita, Y. Takeda and N. Miyamoto, Applied Physics Letters 62, 1003(1993)].

As explained in another document, Ammonium Silicon Fluoride has been found on the walls of vacuum chambers and in the vacuum exhaust lines during plasma assisted semiconductor cleaning and deposition processing [S. Munley, I. McNaught, D. Mrotek, and C. Y. Lin, Semiconductor International, 10/1,(2001)].

It has also been shown that a light emitting powders of Ammonium Silicon Fluoride can be derived from porous Silicon using HF/HNO3 [M. Saadoun, B. Bessais, N. Mliki, M. Ferid, H. Ezzaouia, and R. Bennaceur, Applied Surface Science 210, 240(2003)].

Similarly, [H. Ogawa, T. Arai, M. Yanagisawa, T. Ichiki and Y. Horiike, Jpn. J. Applied Physics 41, 5349(2002)] have shown that Ammonium Silicon Fluoride was formed on Silicon wafers when residual natural oxide reacts with hot Ammonium(NH₃) and Nitrogen Fluoride(NF₃) on the wafer surface.

Also, It was reported that ammonium silicon fluoride has been formed when HF and NH₃ gases are reacted on SiO₂ under vacuum. [P. D. Agnello, IBM J. of Research and Development 46, Number 2/3, 2002)].

There is no application quality cryptocrystal structure in the above mentioned works. Moreover, in these works ammonium silicon fluoride has been obtained as an unintentional, irregular, disordered and contaminated by product.

There is no report in literature on Ammonium X-Fluoride micro- and nanowires.(X=Silicon, Germanium, Diamond)

There is no report on the fact that the dielectric constant of Ammonium X-Fluoride cryptocrystals can be tuned over a large scale and they can be used as insulator.

Micro and nano-electronics are the most important fields of application of this invention. According to International Road Map for Semiconductors(ITRS) [C. Case, Solid State Technology, January, 47(2004)][P. Zeitzoff, R. W. Murto, H. R. Huff, Solid State Technology, 71(2002)], semiconductor industry needs a low-dielectric constant(k) intermetal insulators with dielectric constant which is well under k=3.0.for hi-performance interconnections. Therefore, it is very important to develop low-k di-electrics which are compatible for future integrated circuitry(IC) production. On the other hand, there is a continuing effort in finding a high-k dielectrics for CMOS gate insulation under 1 nanometer for 50 nanometer fabrication node. Our invention also offers a solution to high-k issue with cryptocrystal layers whose dielectric constant can be set at a desired value by diffusion.

In accordance with historical Moore law [G. E. Moore, Electronics 38, 114(1965)[G. E. Moore, IEDM Technical Digest, Washington DC, 11(1975)], down-scaling continues in CMOS technology. Multi-level metallisation is required to accommodate signal integration of a number of active elements. Electrical resistance and parasitic capacitances in these metal interconnects are important factors limiting the IC performance in next generation systems. This causes the industry to move from Aluminum/SiO₂ to Cupper/low-k configuration. While the cupper decreases the line resistance, the low-k dielectric decreases the parasitic capacitance between metal lines.

In order to overcome difficulties in downscaling of transistor dimensions, the capacitance per unit area is to be kept constant. Therefore, there is a need for high-k value dielectrics. These dielectrics can be oxides and silicates such as Al₂O₃, ZrO₂, HFO₂. C. J. Parker, G. Lucovsky and J. R. Hauser, IEEE Electron. Device Lett. (1998); Y. Wu and G. Lucovsky, IEEE Electron. Device Lett. (1998); and H. Yang and G. Lucovsky, IEDM Digest, (1999) have suggested solutions in using these materials. However, there are very tough challenges to overcome concerning the economic cost and number of interfacial defects. Our cryptocrystal technology can offer potential solutions in this field. For example, maintaining advantages of native gate oxide, a high-k dielectric can be formed using cryptocrystals.

The metal lines in integrated circuits are electrically insulated from each other by dielectric insulators. As the IC size becomes smaller, distances between metal lines are decreased, thus leading to an increased capacitance. This causes RC delays, power loss, capacitively induced signals or cross-talks. There is a need for low-dielectric constant insulation layers in lieu of SiO₂.

Polymers with dielectric constant lower than that of SiO₂ are used as interconnect insulator. But, the fact that the polymers are not strong, is an important disadvantage.

Oxides doped with Carbon can be a solution for the low-k dielectrics. It is possible to obtain oxides with dielectric constant smaller than 3.0. However, they present great disadvantages concerning durability.

The performance characteristics gained by down sizing active circuit elements in IC production can be lost in interconnects and packaging elements. In this case, not the speed of transistor but the RC delays at interconnects become important. Moreover, with decreasing dimensions, deeper metal lines are required, thus making intermetal capacitance more important than the interlevel capacitance. In order to overcome these difficulties superior low-k dielectrics and new fabrication methods are required. Current low-k dielectrics consist of oxides and polymers. Cryptocrystals can be a potential solution. Thus, high performance IC's can be realized by avoiding cross-talks among adjacent electric circuits.

One of the approaches is a method using air gaps to lower capacitances [B. Shieh et. al., IEEE Electron Device Letters, 19, no. 1, p. 16-18(1998) [D. L. Wollesen, Low capacitance interconnection, U.S. Pat. No. 5,900,668, issued May 4, 1999]. In these approaches SiO2 has been used as interlevel and intermetal dielectric. U.S. Pat. No. 5,470,802, U.S. Pat. No. 5,494,858, U.S. Pat. No. 5,504,042 and U.S. Pat. No. 5,523,615 patents relate to the possibility of decreasing capacity by using air gaps. But, in these methods, harsh chemicals should be used to form air-gaps. Cryptocrystal technology can offer easier, damage free, low cost solutions in fabricating air-gaps.

This invention relates to ASiF cryptocrystals whose dielectric value can be tuned by several methods and can be synthesized on Si and Si-based wafers. By diffusion, the dielectric constant of ASiF cryptocrystals can be tuned from its minimum value of 1.50 to much higher values(desired). Thus, other properties such as ferroelectric and optical emission can be possed by cryptocrystals.

This invention offers an important alternative to low-cost and high performance low-k technology. Because, it is derived from potential integrated circuit wafers and has a dielectric constant lower than 2.00. This value is smaller than that predicted by ITRS for the year 2007 and beyond.

This invention has important applications in Si CMOS technology and GaAs technology, in increasing the performance of heterojunction bipolar transistors(HBT), high density information storage and information security, microelectronics packaging, photonic component production, IC system cooling, technology integration and sensor production.

The following figures relate to cryptocrystal properties, methods of cryptocrystal layer production and devices in which cryptocrystal layers can be used.

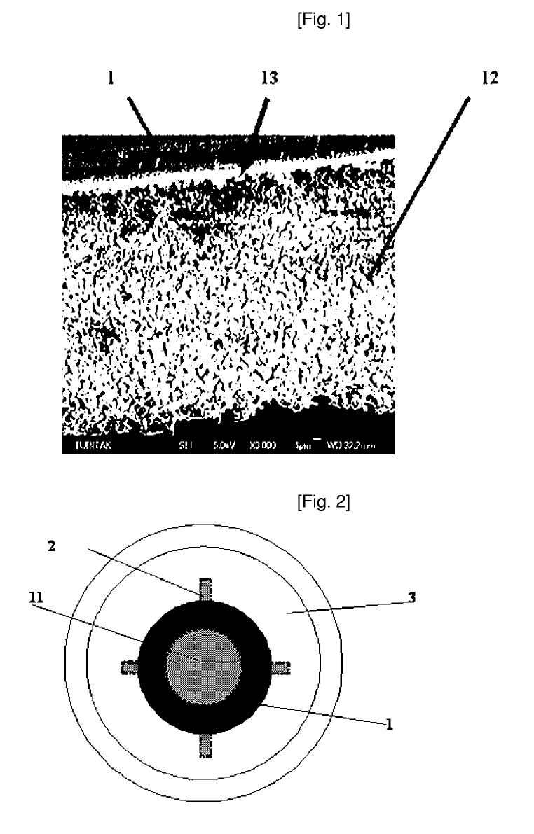

FIG. 1 Cryptocrystal production apparatus which is made of teflon, consists of a liquid containing chamber and cryptocrystal preparation hoder.

FIG. 2 A detailed sketch of the sample holder where the wafer is located.

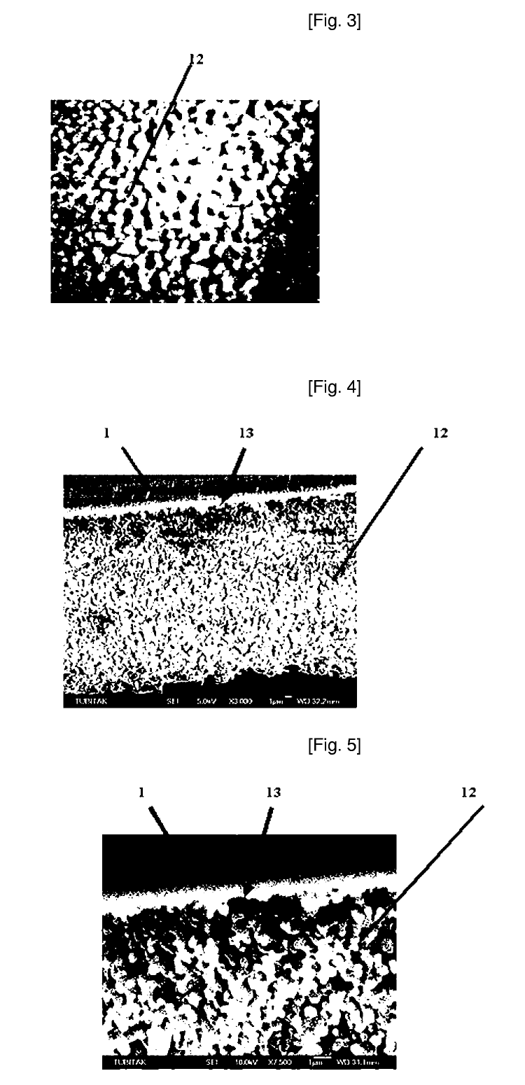

FIG. 3 The surface image of a cryptocrystal layer grown with the apparatus mentioned above as taken under polarization optical microscope This image shows the presence of a porous, complex and indiscernible granular structure.

FIG. 4 Cross-sectional micrograph of a cryptocrystal layer as taken with Scanning Electron Microscope(SEM) at 3.000 magnification. Cryptocrystal structural details are better seen compared to FIG. 3. The thickness of this cryptocrystal layer is 21 μm.

FIG. 5 The interface between the cryptocrystal and the wafer as seen at SEM with a magnification of 7.500. The surface quality and the derivation of cryptocrystals from wafer are clearly shown. There is relatively smooth interface and the cryptocrystal layer sticks well to the wafer.

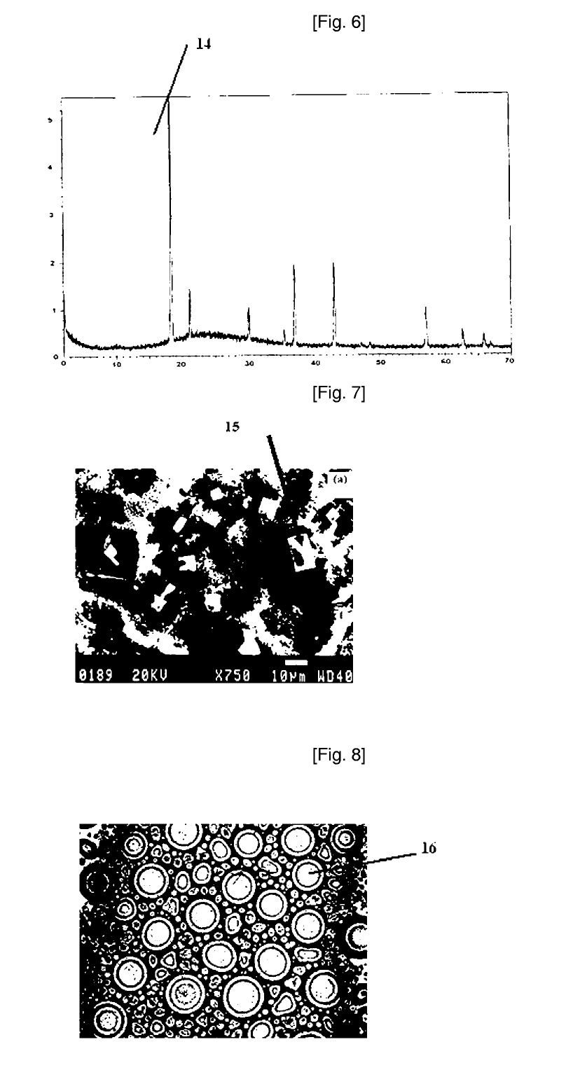

FIG. 6 X-ray diffraction analysis show that the layers are (NH₄)₂SiF₆ and the crystals belong to (4/m-32/m) isometric hexoctahedral system with Fm3m space group [W. L. Roberts, G. R. Rapp and T. J. Cambell, Enc. of Minerals, 2^{nd} Ed., Kluwer Academic Publishers, Dordrecht, 1990].

FIG. 7 The results of x-ray diffraction analysis have been confirmed by FTIR analysis through the presence of vibrational modes of (NH₄)₂SiF₆ groupings. The analysis indicate that the observed vibrational modes at 480 cm⁻¹, 725 cm⁻¹, 1433 cm⁻¹ and 3327 cm⁻¹ belong to N—H and Si—F bondings.

FIG. 8 The changes that occurred at the ASIF surface and behavior of the dielectric structure after annealing are shown. Although, the surface is not protected during annealing, there is still a part sticking to the surface after 200° C. Moreover, bulk crystals of various dimensions are formed on the surface.

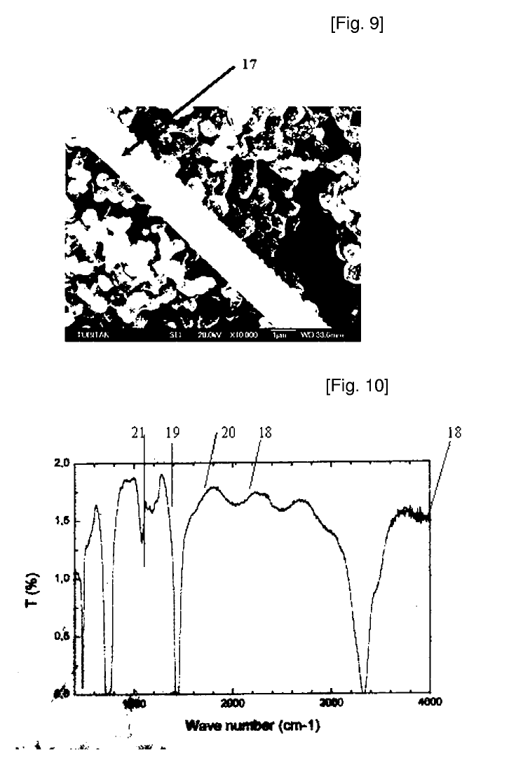

FIG. 9 It is possible to write selectively on the wafer surface to form lithographic structures without using photolithography. The figure shows the result of selective writing using cryptocrystal methods.

FIG. 10 Another important feature of cryptocrystals is that they can be transformed into micro- and nano-wires. It is possible to form straight wires with dimensions ranging from few nanometers up to 1000 nm as shown in the figure. With this method, the straight wires with lengths up to 100 mm can be produced.

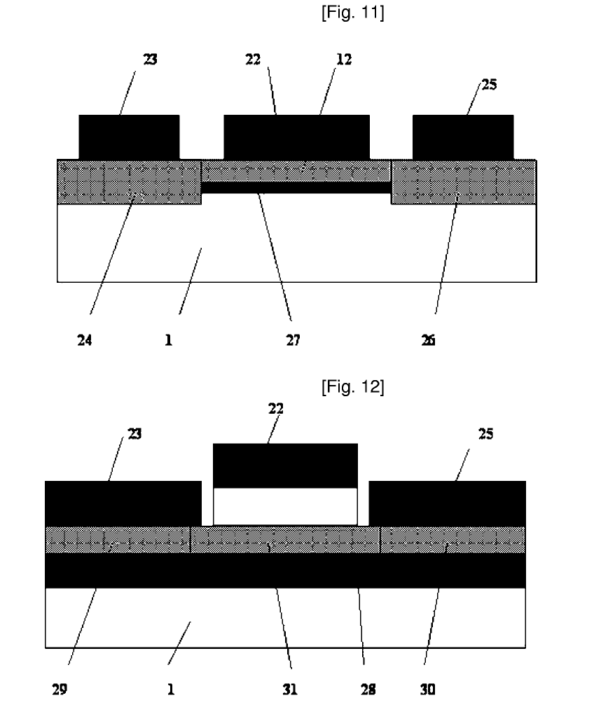

FIG. 11 The use of cryptocrystals as insulating layer in field effect transistors is shown. The Source and Drain regions are located in the first surface and the cryptocrystals are between two regions. The cryptocrystal is directly integrated to natural gate oxide and its dielectric constant is tuned to a desired value by diffusion. In the second situation, there is a native oxide between cryptocrystal and substrate.

FIG. 12 The figure shows how the capacitances between the Base-Collector and Source-Collector can be reduced using cryptocrystal methods.

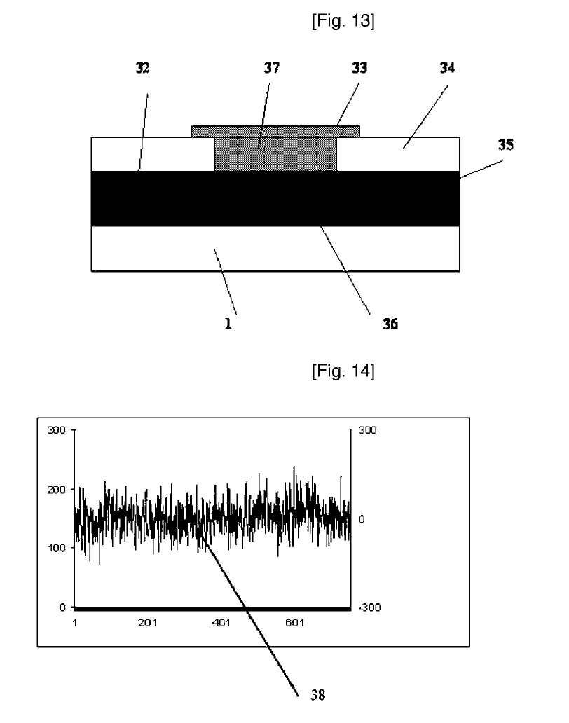

FIG. 13 A crypto chip for generating random numbers. Cryptocrystal layer forms a window and is located just in front of laser or LED cavity.

FIG. 14 Laser scattering trough a cryptocrystal layer and production of physical one-way function using cryptocrystal chip.

The numbers in figures and their correspondance are given below:
1. Wafer or Substrate
2. Gas exhaus channel
3. Teflon container
4. Vapor chamber
5. Chemical mixture
6. Thermometer
7. Ph meter
8. Teflon block
9. Liquid exctraction valve
10. Nitrogen flashing valve
11. Process chamber orifice
12. ASiF cryptocrystals
13. Wafer and cryptocrystal interface
14. (111) major diffraction peak
15. Single ASiF crystals
16. Cryptocrystal dots formed selectively on Si
17. ASiF micro- and nano-wires
18. N—H vibrational modes
19. Si—O vibrational mode
20. Si—F vibrational mode
21. Deformation mode
22. Transistor gate metal
23. Transistor source metal
24. Source
25. Drain metal
26. Drain
27. Gate oxide layer (SiO₂)
28. HBT collector
29. Cryptocrystal HBT source region
30. Cryptocrystal HBT Drain region
31. Hetero Bipolar transistor(HBT) Base region
32. VECSEL active region
33. Protection layer
34. Insulator
35. Top Bragg reflector
36. Bottom Bragg reflector
37. Cryptocrystal transparent window
38. He—Ne laser scattering through cryptocrystal

A method for synthesizing ammonium silicon fluoride(ASiF) on Silicon (Si) and Si based wafers has been developed. In this method, we have used the vapor phase growth technique that we have already developed [S. Kalem and O. Yavuz, OPTICS EXPRESS 6, 7(2000)]. With this method, we have grown cryptocrystal layers by having the vapors of Hidrofluoric Acid (HF) and Nitric Acid (HNO3) reacted on wafer surface. Cryptocrystal layers having white granular color were synthesized on wafers at 1 μm/hour growth rates.

The advantages of this technique are: i) no electrical contacts are required, ii)possibility of writing on surfaces selectively, iii) layers are homogeneous, iv) thickness can be controlled, v) possibility of forming diffusion barrier in etching processes, vi) cost effective compared to other conventional techniques vii) has a cryptoclrystalline property.

Cryptocrystal ammonium silicon fluoride layers (NH₄)₂SiF₆(ASiF) are formed on state-of-the-art-wafers when vapor of a mixture of conventional chemicals are reacted on wafers. This method is called as Chemical Vapor Processing (CVP) and involves the following steps:

a) The preparation of teflon growth chamber and ultrasound cleaning processes;

b) Preparation of a chemical mixture containing HF:HNO₃ with ratios (4-10):(1-8) and 25-50% hidrofluoric acid (HF) and 55-75% nitric acid (HNO₃);

c) Flushing the mixure with Nitrogen and priming the mixture for 10 second with a piece of wafer;

d) Closing entirely the orifice with a wafer to be processed;

e) Making sure that the reaction products are evacuated from the chamber through exhaust channels;

f) Controlling Ph and temperature;

g) Cryptocrystal layers are formed on the wafer by Silicon mediated coupling reactions between HF and HNO₃ species on the wafer following the equation

X+6HF+2HNO₃→(NH₄)₂XF₆+3O₂

Wherein X can be Si, Ge or C.

h) Wafer is transformed into a cryptocrystal layer at a rate of 1 μm;

i) Cryptocrystal layers can be annealed and their strength and density can be enhanced;

j) Transformation of cryptocrystals into nanostructures and particularly to micro- and nano-wires at above 50° C. under nitrogen atmosphere.

Here are the properties of wafers used in cryptocrystal layer production:

1. Resistivities between 5-10 Ohm-cm

2. p-type, Boron doped, (100) and (111) oriented Si

3. n-type, Phosphor doped, (100) and (111) oriented Si

4. Silicon native oxide(thermal oxide) on Silicon SiO₂/Si

5. Stochiometric Si₃N₄ on Silicon (Si/Si₃N₄)

6. Si₁₋ₓGeₓ, x<0.3 (Si₁₋ₓGeₓ on Si)

Cryptocrystal production apparatus consists of a substrate(1), gas exhaust channel for reaction by products(2), teflon container (3), vapor processing chamber(4), chemical liquid mixture(5), Ph meter (7), chemical liquid extraction gate (9), heater block(8) and temperature controller(6), orifice and sample holder(11) and nitrogen flashing(10).

Cryptocrystal layers are formed of undiscernable particles(12) as evidenced by optical polarization microscope and even by scanning electron microscope(SEM). In addition, they have smooth interfaces(13) and are well integrated to wafer as evidenced SEM interfacial studies.

X-ray diffraction analysis indicate that the cryptocrystals grown preferentially in the <111> direction(14). Diffraction peaks and their relative intensitis are summarized in Table-1.

TABLE 1
X-ray diffraction data summarizing diffraction peaks observed
in cryptocrystals of ASiF. Wherein, teta, d and I/I1 are diffraction
angle, distance between planes and normalised diffraction
intensities, respectively.

| Peak No: | 2 Teta (Degree) | d (Angstrom = 10⁻⁸ cm) | I/I1 |
|---|---|---|---|
| 1 | 18.3401 | 4.83355 | 100 |
| 2 | 21.2009 | 4.18734 | 19 |
| 3 | 30.1452 | 2.96221 | 15 |
| 4 | 35.4952 | 2.52703 | 7 |
| 5 | 37.1360 | 2.41906 | 39 |
| 6 | 43.1362 | 2.09545 | 43 |
| 7 | 57.0333 | 1.61348 | 22 |
| 8 | 62.6247 | 1.48219 | 9 |
| 9 | 65.8394 | 1.41739 | 7 |

Cryptocrystals(12) having white color, are formed on wafers(1) in the form of regular thin layers. The annealing experiments indicatate that ASiF stays on the surfaceM up to about 150° C. It is decomposed above this temperature.

Depending on annealing temperature, bulk crystals(15) of ASiF are formed on the surface. The dimensions of these crystals can be up to 15 μm×30 μm.

Cryptocrystal can be selectively realized as dots(16) on wafers,

Nanowires(17) with dimensions ranging from few nanometers up to one micrometer and lengths up to 50 μm were produced. Moreover, variety of nanometer structures and particularly nanobranches were produced.

Room temperature optical properties of ASiF cryptocrystals exhibit the vibrational peaks as summarized in Table-2. The frequencies are associated with vibrations of various bonding configurations of N—H(18), Si—O(19) ve Si—F(20) modes in ASiF. The Si—O vibrations are related to the presence of a native oxide layer at the interface.

Table 2, A summary of FTIR data for ASiF cryptocrystals, wherein, VS:Very Strong, S:Strong, M:Medium, W:Weak, VW:Very Weak.

TABLE 2

| Frequency | | |
|---|---|---|
| ω(cm⁻¹) | Description | Intensity |
| 480 | N—H wagging or Si—F deformation | VS |
| 725 | Si—F stretching | VS |
| 1083 | Si—O stretching (Str) | M |
| 1180 | Si—O Asymmetric stretching(Asym Str) | W |
| 1433 | N—H Bending or deformation mode | VS |
| 2125 | Si—H Stretching | VW |
| 3327 | N—H symmetric stretching(sym str) | VS |
| 3449 | N—H Degenerate stretching | M |

FTIR analysis indicate that ASiF has strong absorption notches at 3 μm(18), 7 μm(18), 13.6 μm(20) and 20.8 μm(21), and thus they can be used in optical applications.

This invention relates to the use of cryptocrystals in integrated circuits. In Field Effect Transistors (FET) the Source(24) and Drain (26) regions are located in the first surface and within the wafer and transistor gate(22) or channel insulating layer(12) is in between these regions. Channel insulating layer(12) is formed of cryptocrystalline material. ASiF cryptocrystal with its tunable dielectric constant value can minimize leakage currents in FET's thus leading to an advantage. In FET's, Cryptocrystal dielectric can directly form an interface with wafer thus reducing leakage currents. In other case, a thin native oxide(27) can be kept between cryptocrystal and wafer. The latter configuration is effective in reducing density of states at the interface.

In another application of this invention, cryptocrystal layer is placed in between Source(23)-Collector(28) and Drain (25)-Collector(28) in (Hetero Bipolar Transistor, HBT) transistors to reduce capacitances and thus increasing high frequency performance of HBT's. Above mentioned capacitances play an important role in III-V compound semiconductor based (GaAs/AlGaAs bazli) HBT's [M. Mochizuki, T. Nakamura, T. Tanoue and H. Masuda, Solid State Electronics 38, 1619(1995) and SiGe based HBT's [U. König and H. Dambkes, Solid State Electronics 38, 1595(1995)]. In such a device, cryptocrystal layers are located in both sides of the Base region(31) and underneath of the Source(29) and the Drain(30) regions. In this structure, after transistor structure formed, both sides of the Base have been transformed into law dielectric constant cryptocrystal regions using above mentioned methods.

With increasing demand for ultra high density and high speed applications, there is an increasing interest for new high performance information storage systems [H. Coufal and G. W. Burr, International Trends in Optics, 2002] [U.S. Pat. No. 6,846,434]. In another application of this invention, we offer alternative solutions to solve high performance information storage. Using cryptocrystals, it would be possible to obtain ultra high density memory cells(20) on electronic wafers. In this application it has been possible to write selectively on Silicon based wafers by forming cryptocrystal cells(16). The fact that cryptocrystals can have phase change(16) at relatively low temperatures, offers the possibility of erasing and rewriting. Thus, the fast phase change feature at low temperatures enables fast writing applications. Moreover, with 8.5 nm unit cell dimension of ASiF cryptocrystals, information storage densities of the order of Th/cm² can be possible. Novelties brought by cryptocrystal technology in this field are: i) possibility of writing on microelectronic wafers without photolithography, ii) offer of high density information storage at Tb/cm² range, iii) high speed erasing and rewriting.

In information security applications, cryptocrystals are used in vertical cavity lasers or LED's [A. C. Tpper, H. D. Foreman, A. Garnache, K. G. Wilcox, S. H. Hoogland, J. Phys. D: Appl. Phys. 37, R75(2004)], right above the active region(32) and top Bragg reflector (35) forming a cryptocrystal window (37). Thus, the laser or LED surface has been transformed into a transparent window. Here the ASiF has to be protected by a cap layer(33). Physical one-way functions can be produced with such a laser/LED chip. The scattering of a He—Ne laser from ASiF (38) shows the feasibility. The scattering indicates the presence of a random structure. This proves that cryptocrystals can be used in generating secure keys in information security. This method is more cost effective and can be beter integrated to IC's compared to CMOS applications [A. Fort, F. Cortigiani, S. Rocchi, and V. Vignoli, Analog Integrated Circuits and Signal Processing 34, 97(2003) and other optical applications using passive elements [R. Pappu, B. Recht, J. Taylor and N. Gershenfeld, Science 297, 2026(2002)].

This invention can be used to bind two wafers together. The method includes the formation of cryptocrystal layers on the surfaces of both wafers by CVP and pressing two wafers together under H₂O, Nitrogen or Hidrogen(H₂) at high temperature.

1. A method for synthesizing optical quality cryptocrystals and nanostructures in a teflon container after ultrasound cleaning on state-of-the-art semiconductor wafers, the cryptocrystals having low dielectric constant whose dielectric constant can be tuned and can possess magnetic and optical emission features, comprising following steps:
a) Flashing and priming of chemical mixture selected from HF, HCl, HNO₃, H₂ SO₄ acid groups and forming chemical vapors in a teflon container(3),
b) Covering the orifice of the reaction chamber with the wafer to be processed,
c) Evacuation of reaction by products and over pressure in the reaction chamber through exhaust channels(2),
d) Adjusting temperature (6) and Ph (7) values to be between 10° C.-50° C. and 1-6, respectively,
e) Having a vapor of chemical mixture selected from HF, HCl, HNO₃, H₂SO₄ acid groups and H2O reacted on wafer surface, thus transforming wafer surface into cryptocrystals with high quality interfaces(13).
f) Enhancing the strength and density of cryptocrystals by thermal curing.
g) A method for growing cost effective epitaxial layers of diamond, SiC, III-V semiconductors and nitrides such as GaN, InN, AlN and II-VI semiconductors such as ZnSe, CdSe, CdS on cryptocrystal layers
h) Transforming cryptocrystal layers into Micro- and Nano-wires(21) under Nitrogen atmosphere by heating and/by metal evaporation.

2. A method according to claim 1 for synthesizing optical quality cryptocrystals and nanostructures in a teflon container after ultrasound cleaning on Gallium Arsenide and/or Silicon based wafers, the cryptocrystals having low dielectric constant whose dielectric constant can be tuned and can possess magnetic and optical emission features, comprising following steps:
a) Flashing and priming of chemical mixture selected from HF, HCl, HNO₃, H₂ SO₄ groups and priming the mixture for 5-30 second with a piece of wafer consisting of Gallium arsenide and/or silicon based wafers
b) Covering the orifice of the reaction chamber with the wafer to be processed,
c) Evacuation of reaction by products and over pressure in the reaction chamber through exhaust channels,
d) Adjusting temperature(6) and Ph(7) values to be between 10° C.-50° C. and 1-6, respectively,
e) Having a vapor of chemical mixture selected from HF, HCl, HBR, HNO₃, H₂ SO₄ acid groups and H2O reacted on wafer X (X═Si, Ge, C, GaAs) surface at X mediated reaction, thus transforming wafer surface into cryptocrystals
f) Enhancing the strength of cryptocrystal layers by diffusing elements such as C, N, O and metals into cryptocrystal matrix and by programmable annealing between 50-400° C.
g) A method for growing cost effective epitaxial layers of diamond, SiC, III-V semiconductors and nitrides such as GaN, InN, AlN and II-VI semiconductors such as ZnSe, CdSe, CdS on cryptocrystal layers
h) Transforming cryptocrystal layers into Micro- and Nano-wires(21) under Nitrogen atmosphere at 30° C.-200° C. and metal evaporation.

3. A method according to claim 2 for synthesizing optical quality ammonium silicon fluoride (ASiF) cryptocrystals and nanostructures in a teflon container after ultrasound cleaning on Silicon based wafers, the cryptocrystals having low dielectric constant whose dielectric constant can be tuned and can possess magnetic and optical emission features, comprising following steps:
a) Flashing and priming of chemical mixture selected from HF, HNO₃, H₂O groups and priming the mixture for 5-30 second with a piece of wafer consisting of silicon based wafers
b) Covering the orifice of the reaction chamber with the wafer to be processed,
c) Evacuation of reaction by products and over pressure in the reaction chamber through exhaust channels,
d) Adjusting temperature(6) and Ph(7) values to be between 10° C.-50° C. and 1-6, respectively,
e) Having vapor of HF, HNO3, H2O reacted on wafer surface at silicon mediated reaction thus transforming wafer surface into cryptocrystals.
f) Enhancing the strength of cryptocrystal layers by diffusing elements such as C, N, O and metals into cryptocrystal matrix and by programmable annealing between 50-400° C.
g) A method for growing cost effective epitaxial layers of diamond, SiC, III-V semiconductors and nitrides such as GaN, InN, AlN and II-VI semiconductors such as ZnSe, CdSe, CdS on cryptocrystal layers so grown,
h) Transforming cryptocrystal layers into Micro- and Nano-wires(21) under Nitrogen atmosphere at 30° C.-200° C. and/by metal evaporation.

4. A method according to claim 3 wherein nano structures which have been produced under nitrogen atmosphere at 50° C. have lateral dimensions ranging from few nanometers to one micrometer with lengths up to 50 micrometer wherein said nanowires and microwires are made of ASIF.

5. A method according to claim 3 wherein nanostructures with waveguides and electron conduction channels and color centers can be obtained by high power pulsed lasers using cryptocrystals

6. A method according to claim 3 wherein chemicals are of hidrofluoric acid (HF) ve nitric acid (HNO₃).

7. A method according to claim 6 wherein the volume ratios of acids are HF:HNO3 (4-10):(1-8).

8. A method according to claim 7 wherein acids used are of electronic grade and % 25-50 hidrofluoric acid ve % 55-75 nitric acid by weight.

9. A method according to claim 3 wherein homogenous cryptocrystal layers having desired thickness or depth have been grown on state-of-the-art Silicon based wafers depending on the type of application.

10. A method according to claim 3 wherein the state-of-the-art wafers include silicon nitride (Si₃Ni₄), silicon dioxide (SiO₂), silicon germanium alloys (Si1-xGex) and silicon carbide.

11. The method of transforming said wafers in claim 10 wherein Ge rate is between 0.01 and 0.50.

12. A method of cryptocrystal growth according to claim 3 wherein cryptocrystal growth rate is 1 micrometer per hour.

13. A method of cryptocrystal growth according to claim 3 wherein said cryptocrystal layer can be used in cost effective crystal growth comprising:
a) Formation of cryptocrystal layer on said wafer
b) Enhancement of cryptocrystal layer properties and surface preparation
c) Growth of group IV semiconductors such as Diamond, SiC; nitrides such as GaN, InN, AlN and II-VI compound semiconductors such as ZnSe, CdSe, CdS.
d) Lifting off semiconductor layers from cryptocrystals.

14. A method according to claim 3 wherein cryptocrystals are inorganics and their dielectric constant is tunable.

15. A method according to claim 14 wherein the dielectric constant of cryptocrystal can be adjusted by evaporation and diffusion.

16. A method according to claim 15 wherein the dielectric constant of cryptocrystals is less than 2.0 and depending on application, said dielectric constant can be set at a desired value by elemental incorporation.

17. A method of cryptocrystal layer and nanostructure growth according to claim 3 wherein said cryptocrystals can have magnetic and optical emission properties and their dielectric constant can be adjusted from 1.5 to a desired value.

18. A method according to claim 3 wherein annealing is realized by thermal heating and radiation(Infrared and ultraviolet).

19. The integrated circuit system having interconnects and consisting of:
a) Metal lines interconnecting electronic devices on wafer
b) Wherein cryptocrystal dielectrics are prepared according to our CVP method wherein said cryptocrystals have low dielectric constant.
c) Air gaps between signal carrying metal lines that are formed by using cryptocrystal methods

20. The interconnect device according to claim 19 wherein metal conduction lines are made of Silver, Copper, Aluminum or Gold.

21. The interconnect device according to claim 19 wherein said cryptocrystals are Silicon, Germanium or GaAs based.

22. The interconnect system according to claim 19 wherein said wafers are Silicon, Gallium Arsenide, ceramic or glass based.

23. The interconnect system according to claim 19 wherein the dielectric constant of cryptocrystals between the metal lines is less than 2.0.

24. A method for low-k solution wherein both native oxide advantage is maintained and the leakage current problem caused by native oxide has been solved by introducing high-dielectric constant insulators consisting of;
a) Formation of native oxide (SiO2) with desired thickness by thermal oxidation on wafers
b) Transformation(12) of top part of native oxide to cryptocrystal by CVP methods
c) Adjusting(13) dielectric constant of cryptocrystals at a value between 1.5-15
d) Maintaining a high quality of interface necessary for electron conduction and thus avoiding leakage currents

25. The heterojunction bipolar transistor(HBT) device wherein left and right sides of Base region is made of Silicon based materials wherein the regions between Source(29)-Collector(28) and Drain(30)-Collector(28) under Source (23) and Drain (25) regions are transformed in to cryptocrystals produced by CVP method.

26. The heterobipolar transistor device according to claim 25 wherein said transistor can be produced from combination of III-V compound semiconductors such as (Ga, Al)As, (In, Ga)As, (In, Ga)P wherein base regions under the source and the Drain are made of Silicon based materials.

27. The transistor device according to claim 25 wherein said transistor is made of a combination of group III-nitrides such as (Ga, Al)N, (In, Ga)N, (In, Al)N.

28. A device for security chips generating physical one-way functions and random numbers(39) and information processing systems using these devices that are produced by CVP, wherein cryptocrystals (12) form a transparent window (13) and a protection layer which are located on top of the active region(32) and Bragg reflectors(35) in a surface emitting laser or LED.

29. A method for binding two different wafers wherein cryptocrystals are formed on the surface of both wafers by CVP method wherein both surfaces are pressed together at high temperature under H₂O, Nitrogen or Hydrogen.

30. The optoelectronic devices wherein cryptocrystals and cryptocrystal methods are used to produce laser, LED, microprocessors and optical devices.
